(19) United States
(12) Patent Application Publication
(10) Pub. No.: US 2010/0190333 A1
(43) Pub. Date: Jul. 29, 2010

(54) METHOD OF FORMING CONNECTION TERMINAL

(75) Inventors: Myeong-Soon PARK, Seoul (KR); Eunchul Ahn, Yongin-si (KR); Hyunsoo Chung, Hwaseong-si (KR); Seokho Kim, Bucheon-si (KR); Do-Yeon Choi, Seoul (KR); Jinho Chun, Seoul (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/691,780

(22) Filed: Jan. 22, 2010

(30) Foreign Application Priority Data
Jan. 28, 2009 (KR) 2009-6655

(51) Int. Cl. H01L 21/60

(52) U.S. Cl. 438/615; 257/E21.509; 438/612

(57) ABSTRACT

A method of forming a connection terminal may include preparing a substrate, forming a first conductor of a tube shape having an opened upper portion on the substrate, forming a second conductor on the first conductor, and annealing the second conductor so that a portion of the second conductor extends in an internal space of the first conductor through the opened upper portion.

### CROSS-REFERENCE TO RELATED APPLICATIONS

This U.S. non-provisional patent application claims priority under 35 U.S.C. §119 of Korean Patent Application No. 10-2009-0006655, filed on Jan. 28, 2009, the entire contents of which are hereby incorporated by reference.

### BACKGROUND

1. Field of the Invention

The present disclosure herein relates to methods of a forming connection terminal, and more particularly, to methods of forming a connection terminal which is capable of withstanding an external shock.

2. Description of the Related Art

A flip chip package or a wafer level package includes a solder ball as a connection terminal for electrical connection between a semiconductor integrated circuit (hereinafter it is referred to as a semiconductor chip) and an external device. For example, a flip chip package may include a semiconductor chip, a printed circuit board, and solder balls which are interposed between the semiconductor chip and the printed circuit board to electrically connect the semiconductor chip and the printed circuit board.

However, the solder balls of the semiconductor package may be easily damaged by a temperature change and by an external physical shock. For example, since the semiconductor chip and the printed circuit board have different coefficients of thermal expansion from each other, a stress may be applied to the connection terminal when the semiconductor chip is heated or cooled. The stress may generate a crack in the connection terminal or may cause the solder balls to be separated from the printed circuit board. In particular, since the solder balls are positioned on a level plane of a semiconductor chip and a printed circuit board, if the stress (e.g. a shearing force) is applied to the semiconductor chip and the printed circuit board along a direction parallel to the level plane, junction parts between the semiconductor chip and the solder balls and between the printed circuit board and the solder balls may be easily damaged.

### SUMMARY

Embodiments of the present general inventive concept provide methods of forming a connection terminal.

Additional aspects and utilities of the present general inventive concept will be set forth in part in the description which follows and, in part, will be obvious from the description, or may be learned by practice of the general inventive concept.

Features and/or utilities of the present general inventive concept may be realized by a method including preparing a substrate, forming a first conductor of a tube shape having an opened upper portion on the substrate, forming a second conductor on the first conductor, and annealing the second conductor so that a portion of the second conductor extends in an internal space of the first conductor through the opened upper portion.

The forming of the first conductor may include forming a photoresist layer on the substrate, forming a depression portion of the tube shape exposing the substrate on the photoresist layer, and forming metal material on the depression portion.

The preparing of the substrate may include forming an under bump metal layer electrically connected to an electric device on the substrate. The forming of the depression portion may include exposing an edge region of the under bump metal layer.

The second conductor may be formed to have a volume greater than a volume of the internal space.

The annealing of the second conductor may include reflowing the second conductor in a vacuum atmosphere.

The forming of the first conductor may include forming metal material having a higher melting point than the second conductor.

The forming of the first conductor may include forming metal material having a higher melting point than the second conductor.

The forming of the first conductor may include forming metal material having a higher strength than the second conductor.

The forming of the first conductor may include forming metal material including at least one of copper (Cu), nickel (Ni) and gold (Au) and wherein forming the second conductor comprises forming metal material including at least one of tin (Sn), plumbum (Pb) and silver (Ag).

Features and/or utilities of the present general inventive concept may also be realized by a method including preparing a substrate including an under bump metal layer, forming a solder portion comprising both a lower portion of a cylindrical shape attached to the under bump metal layer and an upper portion of a sphere shape on the substrate, and forming a solder portion supporter surrounding the lower portion on the substrate.

The forming of the solder portion supporter may include forming metal material having a higher strength compared with the solder portion on an edge region of the under bump metal layer.

Features and/or utilities of the present general inventive concept may also be realized by a method of forming a connection terminal including forming a support structure on a substrate and forming a conductive material in a center portion of the support structure and extending out of an upper portion of the support structure. The conductive material may be located above and electrically connected to a conductive contact of the substrate.

The support structure may be tube-shaped.

Forming the support structure may include mounting a tube-shaped structure to the substrate.

Forming the support structure may include forming a photoresist layer on the substrate, forming a tube-shaped cavity in the photoresist layer to expose a portion of the substrate, and filling the tube-shaped cavity with support material.

The exposed portion of the substrate may include a portion of the conductive contact of the substrate, and the support material may be a conductive material.

The conductive contact may have a substantially circular shape, and the exposed portion of the conductive contact may correspond to an outer edge of the circular shape.

Forming the conductive material may include, after forming the tube-shaped cavity in the photoresist layer, filling a lower portion of the tube-shaped cavity with the support material, filling an upper portion of the tube-shaped cavity with the conductive material, removing the photoresist layer, and causing the conductive material corresponding to the upper portion of the tube-shaped cavity to fill the center portion of the support structure and to extend out from an upper end of the support structure.

The conductive material may be caused to fill the center portion of the support structure in an annealing process.

The annealing process may be performed in a vacuum atmosphere.

The conductive material extending out of an upper end of the support structure may have a substantially spherical shape.

The support structure may be of such a height that the conductive material extending out of the upper portion of the support structure may be separated from a surface of the substrate.

The support structure may be composed of a material having a structural strength greater than that of the conductive material.

The support structure may be located outside an outer edge of the conductive contact.

Features and/or utilities of the present general inventive concept may also be realized by a method of forming a connection terminal, the method including forming an external connector to be electrically connected to a metal connection pad of a substrate and forming a support structure between the metal connection pad of the substrate and the external connector so that the external connector is located a predetermined distance from the substrate.

The support structure may include a hollow center, and the method may include forming a conductive material in the hollow center of the support structure to electrically connect the metal connection pad to the external connector.

### BRIEF DESCRIPTION OF THE DRAWINGS

The above and/or other aspects of the present general inventive concept will become apparent and more readily appreciated from the following description of the exemplary embodiments, taken in conjunction with the accompanying drawings, in which:

FIG. 1 is a top plan view illustrating a portion of a semiconductor package including a connection terminal formed by a method in accordance with the present general inventive concept;

FIG. 2 is a cross section view taken along the line I-I′ illustrated in FIG. 1;

FIG. 3 is a flow chart illustrating a method of manufacturing the semiconductor package illustrated in FIG. 1;

FIGS. 4A through 4D are drawings illustrating a process of manufacturing the semiconductor package illustrated in FIG. 1;

FIG. 5 is a drawing illustrating a package module including the semiconductor package to which a technique of the present general inventive concept is applied;

FIG. 6 is a block diagram illustrating an electronic device including a semiconductor device to which a technique of the present general inventive concept is applied;

FIG. 7 is a block diagram illustrating a memory system including a semiconductor device to which a technique of the present general inventive concept is applied;

FIG. 8 illustrates a solder support according to an embodiment of the present general inventive concept; and

FIG. 9 illustrates a connection terminal according to an embodiment of the present general inventive concept.

### DETAILED DESCRIPTION OF THE EMBODIMENTS

Preferred embodiments of the inventive concept will be described below in more detail with reference to the accompanying drawings. The embodiments of the inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Like numbers refer to like elements throughout.

In the drawings, the thickness of layers and regions are exaggerated for clarity. It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

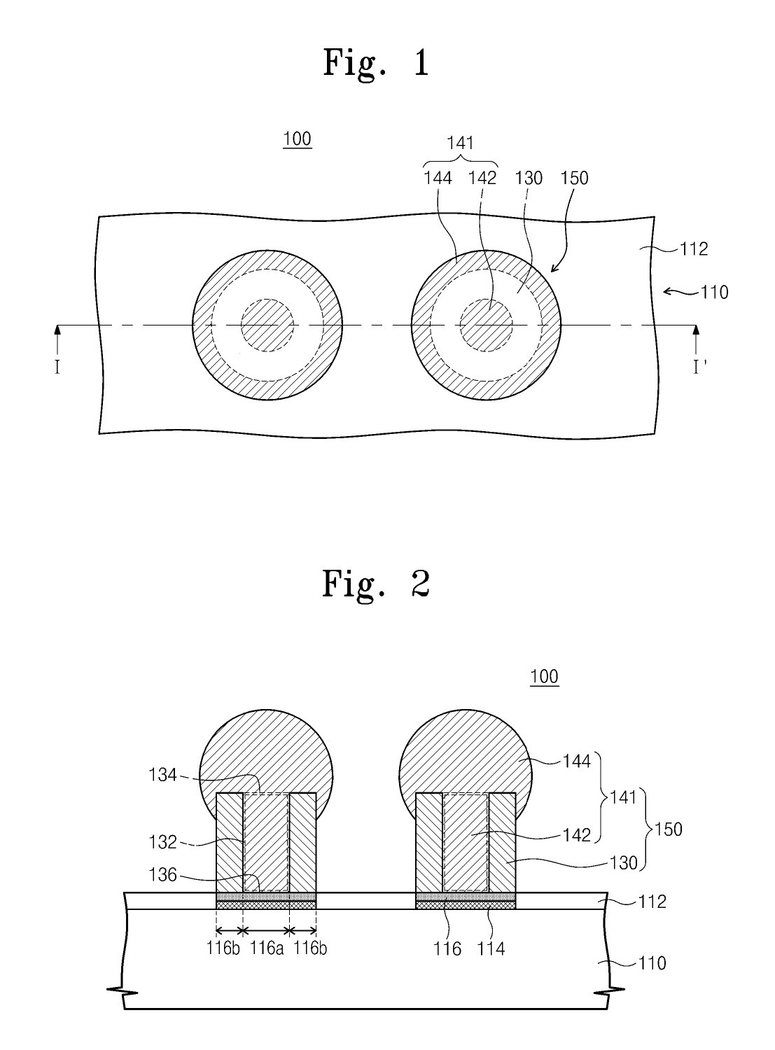

FIG. 1 is a top plan view illustrating a portion of a semiconductor package including a connection terminal formed through the method of forming a connection terminal in accordance with an embodiment of the inventive concept. FIG. 2 is a cross section view taken along the line I-I′ illustrated in FIG. 1.

Referring to FIGS. 1 and 2, a semiconductor package 100 in accordance with embodiments of the present general inventive concept may include a substrate 110 and a connection terminal 150 located on the substrate 110. The semiconductor package 100 may further include an external device (not shown). For example, the semiconductor package 100 may further include a printed circuit board (PCB) electrically connected to the substrate 110 by the connection terminal 150. In this case, the semiconductor package 100 may complete a flip chip package.

The substrate 110 may be a substrate including an electrical device. For example, the substrate 110 may be a substrate including a semiconductor integration chip (IC). The substrate 110 may include an insulating layer 112, a connection pad 114, and an under bump metal layer 116. The insulating layer 112 may surround the connection pad 114 and the under bump metal layer 116 on the substrate 110. The connection pad 114 may be a metal layer electrically connected to an electric device. For example, the connection pad 114 may be a metal pad comprised of aluminum (Al). The under bump metal layer 116 may be disposed on the connection pad 114. The under bump metal layer 116 may include at least one of titanium (Ti), tungsten (W), copper (Cu), nickel (Ni), gold (Au), chrome (Cr) and vanadium (V).

The connection terminal 150 may include a solder portion supporter 130 and a solder portion 141 supported by the solder portion supporter 130. The solder portion supporter 130 may be disposed on the under bump metal layer 116. The solder portion supporter 130 may be disposed on an edge region 116b of the under bump metal layer 116 to expose a central region 116a of the under bump metal layer 116. The solder portion supporter 130 may have a tube shape having an internal space 132 filled by an internal portion 142 and having open ends. In other words, the upper end 134 may connect the internal portion 142, to the external connection portion 144, and the lower end 136 may connect the internal portion 142 to the metal layer 116. The solder portion supporter 130 may be composed of metal material. For example, the solder portion supporter 130 may be composed of metal material including at least one of copper (Cu), nickel (Ni) and gold (Au).

The solder portion 141 may include the internal portion 142 and the external connection portion 144, which may be a solder ball, for example. The internal portion 142 may be a lower portion of the solder portion 141 and the external connection portion 144 may be an upper portion of the solder portion 141. The internal portion 142 may be disposed in the internal space 132 of the solder portion supporter 130. The internal portion 142 may be electrically connected to the external connection portion 144 in the internal space 132 through the opened upper portion 134 to attach to the under bump metal layer 116. Thus, the internal portion 142 may have a cylindrical shape and may be surrounded by the solder portion supporter 130 to be supported by the solder portion supporter 130. Also, the internal portion 142 may electrically connect the under bump metal layer 116 to the external connection portion 144. The external connection portion 144 may be a portion of the connection terminal 150 attached to an external device (not shown). The external connection portion 144 may be exposed to the outside. The external connection portion 144 may have a spherical shape on the solder portion supporter 130.

As described above, since the internal portion 142 is electrically connected to the external connection portion 144, the internal portion 142 and the external connection portion 144 may be formed of the same conductive material and an interface may not be formed between the internal portion 142 and the external connection portion 144.

The solder portion supporter 130 and the solder portion 141 may be formed of different conductive materials. For example, the solder portion supporter 130 may be formed of material having a high melting point compared with the solder portion 141. In addition, the solder portion supporter 130 may be formed of material having a high strength compared with the solder portion 141. For example, when the solder portion 141 is formed of at least one of tin (Sn), lead (Pb), silver (Ag) and an alloy thereof, the solder portion supporter 130 may be formed of at least one of copper (Cu), nickel (Ni), gold (Au) and an alloy thereof.

As described above, the connection terminal 150 in accordance with an embodiment of the present general inventive concept may include the solder portion 141 surrounded and supported by the solder portion supporter 130. The solder portion supporter 130 may be formed of metal material having a high strength and a high melting point compared with the solder portion 141. Accordingly, the solder portion 141 may be effectively protected from an external shock by the solder portion supporter 130. For example, when an external shock such as a bend of the substrate 110 is generated, a stress (e.g., a shearing force) may be applied to the connection terminal 150 in a direction parallel to an upper surface of the substrate 110. In a conventional connection terminal, a crack may be generated in the connection terminal in a direction parallel to the substrate. However, in the connection terminal 150 in accordance with an embodiment of the present general inventive concept, since the solder portion supporter 130 is perpendicular to the substrate 110, a crack radio wave moving to the solder portion 141 may be cut off by the solder portion supporter 130 or a direction of the crack radio wave may be changed from a horizontal direction to a vertical direction. Thus, the solder portion supporter 130 changes the direction of the crack radio wave to effectively reduce the external shock, thereby protecting the solder portion 141 from an external shock. In addition, since the solder portion supporter 130 increases a progressing length of a crack which can be generated in the solder portion 141, a mechanical durability of the connection terminal 150 can be improved compared to a conventional connection terminal.

A method of forming a connection terminal in accordance with an embodiment of the present general inventive conception is described in detail. Descriptions of previously-described portions of the semiconductor package and the connection terminal in accordance with an embodiment of the present general inventive concept may be omitted.

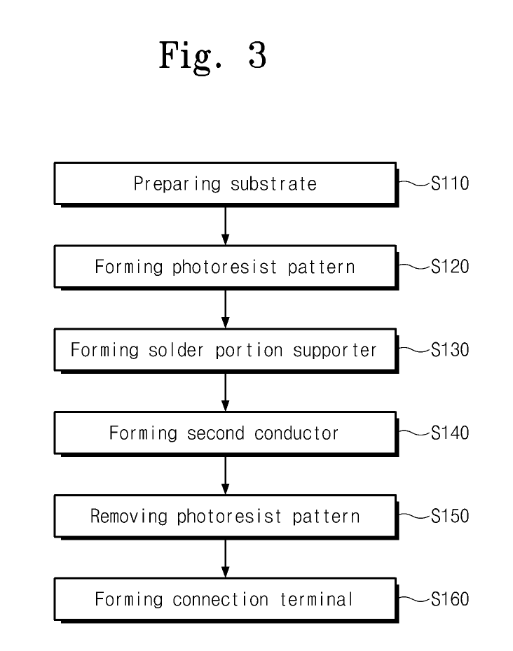

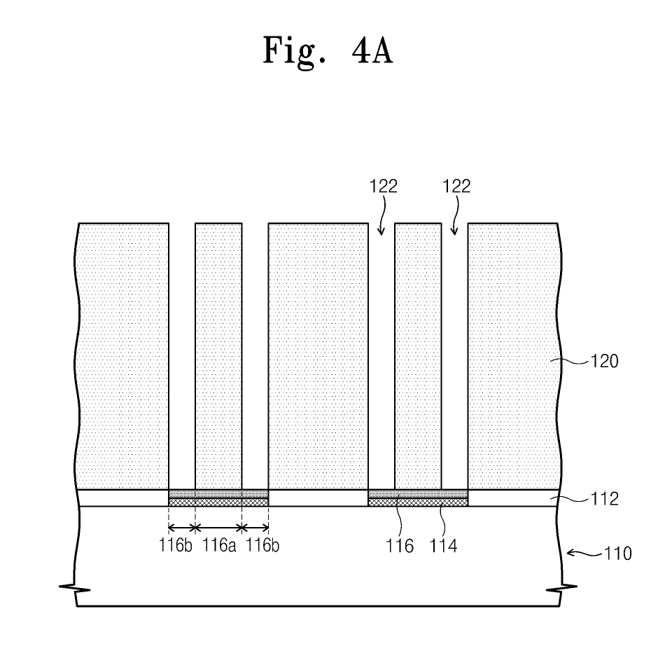

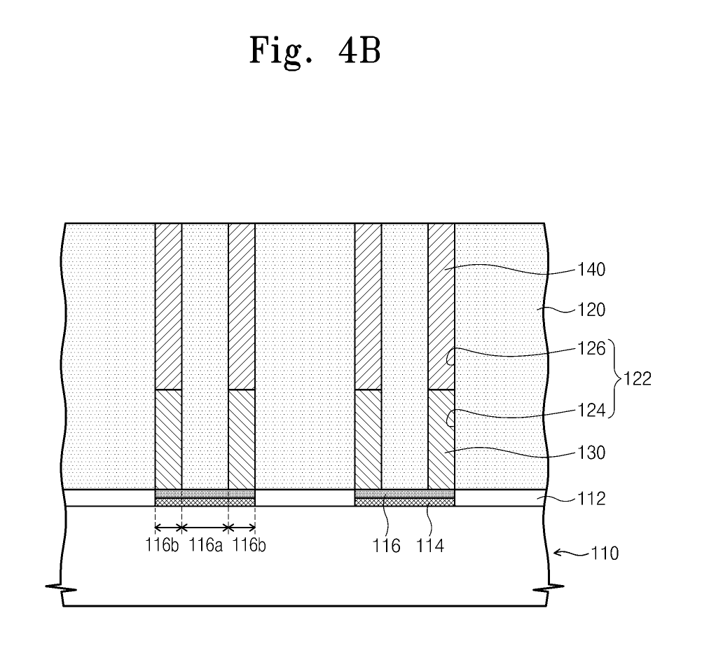

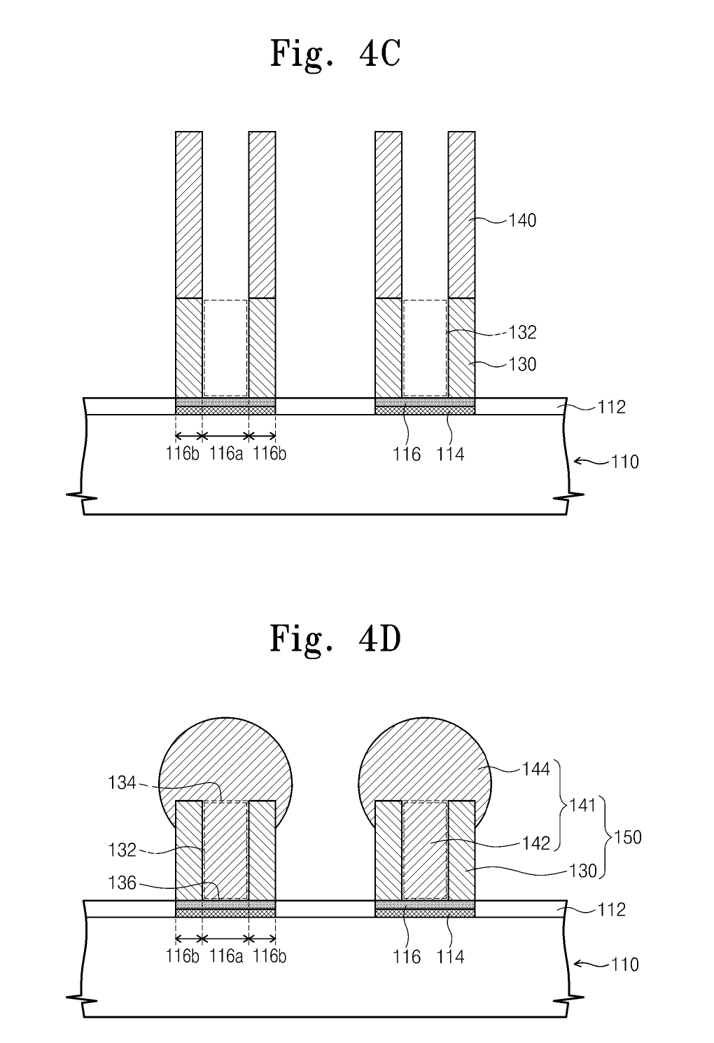

FIG. 3 is a flow chart illustrating a method of manufacturing the semiconductor package illustrated in FIG. 1. FIGS. 4A through 4D are drawings illustrating a process of manufacturing the semiconductor package illustrated in FIG. 1.

Referring to FIGS. 3 and 4A, a substrate 110 may be prepared in operation S110. For example, preparing the substrate 110 may include preparing a substrate including a semiconductor integrated circuit chip. Preparing the substrate 110 may include forming an insulating layer 112, a connection pad 114, and an under bump metal layer 16 on the substrate 110. The connection pad 14 and the under bump metal layer 116 may be sequentially stacked on the substrate 110 and may be surrounded by the insulating layer 112.

A photoresist pattern 120 may be formed on the substrate 110 in operation S120. Forming the photoresist pattern 120 may include forming a photoresist layer on the substrate 110 and forming a depression portion 122 or hole to expose the substrate 110 on the photoresist layer. Forming the depression portion 122 may include forming a hole selectively exposing an edge region 116b of the metal layer 116. The depression portion 122 may have a tube shape. In other words, a hole 122 may be formed in the photoresist layer having a cylindrical or tube shape so that a substantially circular outer edge portion 116b of the metal layer 116 is exposed, but a central region 116a of the metal layer 116 is not exposed.

Referring to FIGS. 3 and 4B, a solder portion supporter 130 may be formed in operation S130. Forming the solder portion supporter 130 may include forming a first conductor 130 in the depression portion 122 of the photoresist pattern 120. For example, forming the first conductor may include forming metal material including at least one of copper (Cu), nickel (Ni), gold (Au) and an alloy thereof in a lower portion 124 of the depression portion 122. Forming the first conductor 130 in the lower portion 124 of the depression portion 122 may include performing a plating process. For example, forming the first conductor in the lower portion 124 of the depression portion 122 may include performing any one of an electroplating process and an electroless plating process. Since the depression portion 122 has a tube shape, the first conductor may be formed as a tube shape. Accordingly, the connection pad 114 and the under bump metal layer 116 surrounded by the insulating layer 112 and the solder portion supporter 130 having a tube shape disposed on the edge region 116b of the under bump metal layer 116 may be disposed on the substrate 110.

A second conductor 140 may be formed in operation S140. For example, forming the second conductor 140 may include forming metal material on an upper portion 126 of the depression portion 122. For example, forming the second conductor 140 may include filling the upper portion 126 with metal material including at least one of tin (Sn), plumbum (Pb), silver (Ag) and an alloy thereof. Forming the second conductor 40 may include a plate process. For example, forming the second conductor 140 may include any one of an electroplating process and an electroless plating process. As a result, the solder portion supporter 130 and the second conductor 140 stacked on the edge region 116b may be disposed on the substrate 110.

Referring to FIGS. 3 and 4C, the photoresist pattern 120 may be removed in operation S150. For example, removing the photoresist pattern 120 may include performing an etching process having an etching selectivity with respect to the solder portion supporter 130 and the second conductor 140. The etching process may include a wet etching process. The metal layer 116 of which the central region 116a is exposed, the solder portion supporter 130, and the second conductor 140 sequentially stacked on the edge region 116b of the metal layer 116 may be disposed on the substrate 110. At this time, the solder portion supporter 130 and the second conductor 140 may have a tube shape.

A volume of the second conductor 140 may be greater than a volume of an internal space 132, so that the second conductor 140 may be used to fill the internal space 132, and, in a subsequent process, a remaining portion of the second conductor 140 after filling the internal space 132 may be formed to be an external connection portion (144 illustrated in FIG. 4D). Generally, a thickness of material to be plated in a plate process may be in proportion to a supply of an electric power being applied to an electrode. Thus, a volume of the second conductor 140 can be controlled to be greater than a volume of the internal space 132 by controlling a supply of an electric power being applied to an electrode during a plate process. For example, a supply of an electric power being applied to an electrode during a plate process of forming the second conductor 140 can be controlled to be greater than a supply of an electric power being applied to an electrode during a plate process of forming the solder portion supporter 130.

Referring to FIGS. 3 and 4D, a connection terminal 150 may be formed in operation S160. Forming the connection terminal 150 may include annealing the second conductor 140. Annealing the second conductor 140 may include performing a reflow of the second conductor 140. Accordingly, a portion of the second conductor 140 is wetted to the solder portion supporter 130 to extend into the internal space 132 through an opened upper portion 134 of the solder portion supporter 130. The portion of the second conductor 140 that extends into the internal space 132 may be attached to the center portion 116a of the metal layer 116 that is exposed via the lower end 136 of the internal space 132. This portion of the second conductor 140 may form the internal conductor 142 of the connection terminal 150. Also, a portion of the second conductor 140 may form the external connection portion 144 having a spherical shape on the solder portion supporter 130.

A void may be formed in the internal portion 142 during an annealing process of the second conductor 140. This is because an external air flows in the internal space 132 with the second conductor 140 while filling the internal space 132 with the second conductor 140. To prevent that, a reflow of the second conductor 140 may be performed at a vacuum atmosphere.

As described above, the connection terminal 150 formed by the method of forming a connection terminal in accordance with an embodiment of the inventive concept may include the solder portion 141 comprised of the lower portion (i.e., the internal portion 142) having a cylindrical shape attached to the substrate 110 and the upper portion (i.e., the external connection portion 144) having a sphere shape, and the solder portion supporter 130 surrounding the lower portion. Thus, the connection terminal 150 which is strong in a temperature change and an external physical shock may be formed by the method of forming a connection terminal.

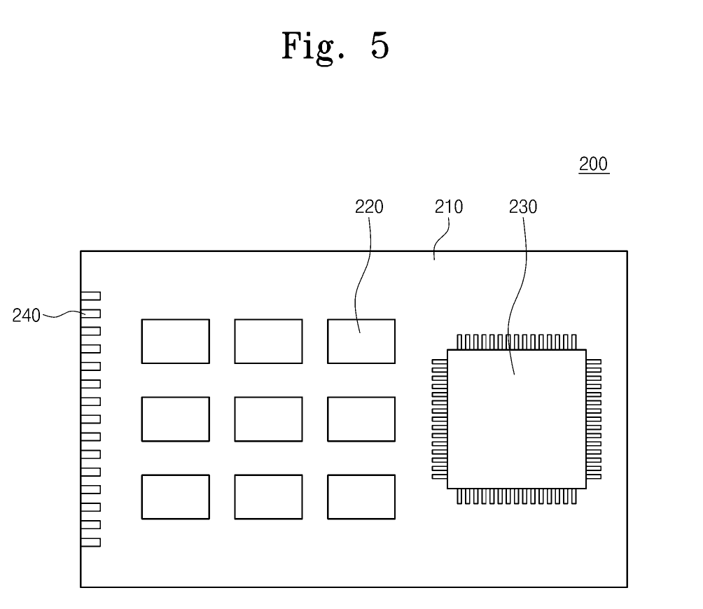

FIG. 5 is a drawing illustrating a package module including the semiconductor package to which a technique of the present general inventive concept is applied. Referring to FIG. 5, the semiconductor package may be applied to various kinds of semiconductor devices and a package module 200 including the semiconductor devices. For example, the package module 200 may be provided as a device including a semiconductor integrated circuit chip 220 and a semiconductor integrated circuit chip 230 packaged by a quad flat package (QFP). The semiconductor package (100 illustrated in FIG. 1) manufactured according to the inventive concept may be included in various types of semiconductor devices 220 and 230. The package module 200 may be formed by installing the semiconductor devices 220 and 230 on a separated semiconductor substrate 210. The substrate may include edge connectors 240 to connect to external devices (not shown). As described above, the semiconductor package 100 in accordance with an embodiment of the inventive concept may include a connection terminal (150 illustrated in FIG. 1) which is strong in a temperature change and an external physical shock. Accordingly, the package module 200 may be strong in a temperature change and an external physical shock.

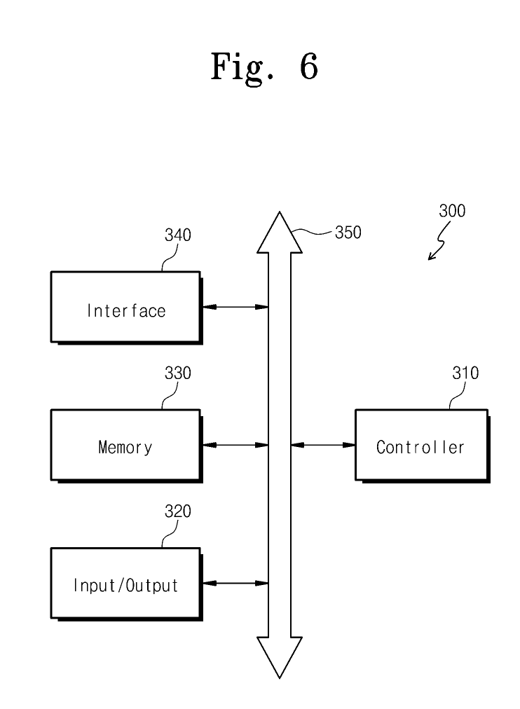

FIG. 6 is a block diagram illustrating an electronic device including a semiconductor device to which a technique of the present general inventive concept is applied. Referring to FIG. 6, the semiconductor package described above may be applied to an electronic system 300. For example, the electronic system 300 may include a controller 310, an input/output device 320 and a memory device 330 combined with one another through a bus 350. The bus 350 may be a path through which data move. The controller 310 and the memory device 330 may include the semiconductor package (100 illustrated in FIG. 1). The input/output device 320 may include at least one of a keypad, a keyboard and a display device. The memory device 330 may store data. The electronic system 300 may further include an interface 340 which transmits data to a telecommunication network or receives data from a telecommunication network. The electronic system 300 may be embodied in a mobile system, a personnel computer, an industrial computer, a wireless communication device, or a logic system performing various functions. As described above, the semiconductor package 100 in accordance with an embodiment of the inventive concept may include a connection terminal (150 illustrated in FIG. 1) which is strong in a temperature change and an external physical shock. Thus, the electronic system 300 may be strong in a temperature change and an external physical shock.

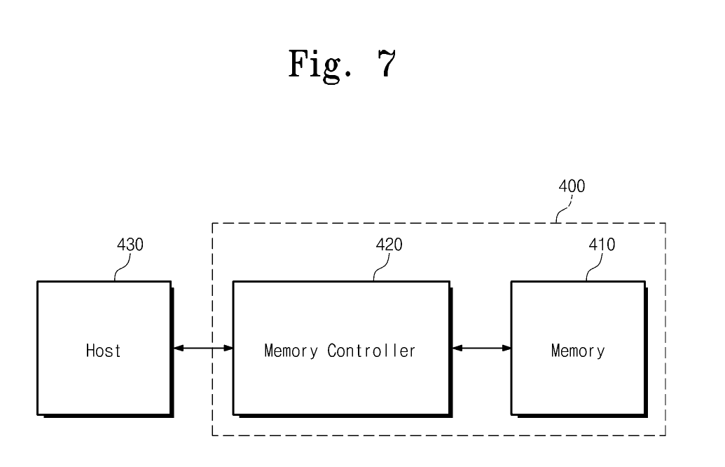

FIG. 7 is a block diagram illustrating a memory system including a semiconductor device to which a technique of the inventive concept is applied. Referring to FIG. 7, the semiconductor device to which a technique of the inventive concept is applied may be provided as a memory card 400. For example, the memory card 400 may include a memory device 410 and a memory controller 420 including the semiconductor package 100 in accordance with an embodiment of the inventive concept. The memory device 410 may include a nonvolatile memory device. The memory controller 420 can control the memory device 410 to readout stored data or store data in response to a request of a read/write of the host 430. As described above, the semiconductor package 100 in accordance with an embodiment of the present general inventive concept may include the connection terminal (150 illustrated in FIG. 1) which is strong in a temperature change and an external physical shock. Thus, the memory card 400 may be strong in a temperature change and an external physical shock.

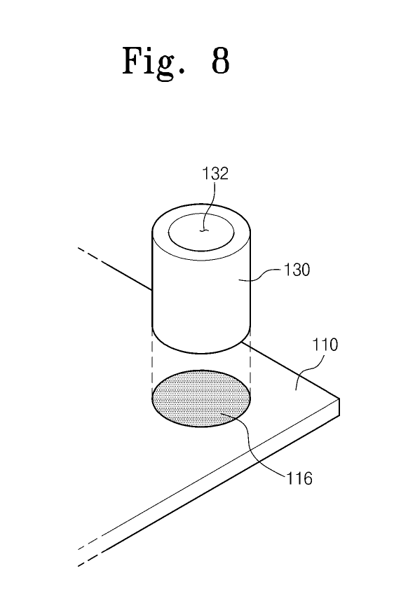

FIG. 8 illustrates an example of a solder supporter 130 according to another embodiment of the present general inventive concept. In FIG. 8, the solder supporter 130 is a pre-formed structure that is mounted onto the metal layer 116 of the substrate 110. Once the solder supporter 130 is mounted to the substrate 110, conductive material, such as solder 141, may be formed in the internal space 132 and extending out of the external space 132, as described above.

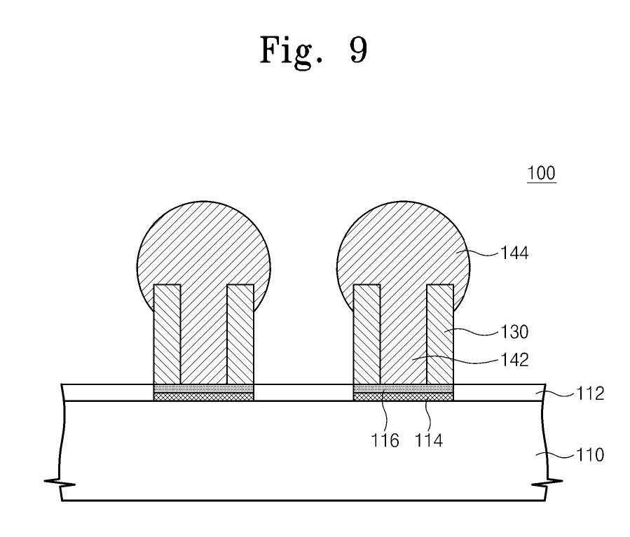

FIG. 9 illustrates a connection terminal 150 according to another embodiment of the present general inventive concept. In FIG. 9, the solder supporter 130 is mounted onto the insulation layer 112 of the substrate 110, rather than onto the metal layer 116, as disclosed in previous embodiments. Consequently, the internal portion 142 may be connected to an entire upper surface portion of the metal layer 116.

A connection terminal formed by the method of forming a connection terminal in accordance with the inventive concept may include a solder portion including a lower portion having a cylindrical shape attached to a substrate and an upper portion having a sphere shape, and a solder portion supporter surrounding the lower portion. Accordingly, a connection terminal which is strong in a temperature change and an external physical shock can be formed by the method of forming a connection terminal in accordance with the inventive concept.

The above-disclosed subject matter is to be considered illustrative, and not restrictive, and the appended claims are intended to cover all such modifications, enhancements, and other embodiments, which fall within the true spirit and scope of the general inventive concept. Thus, to the maximum extent allowed by law, the scope of the general inventive concept is to be determined by the broadest permissible interpretation of the following claims and their equivalents, and shall not be restricted or limited by the foregoing detailed description.

For example, the solder support 130 may be alternatively described as a support structure, a conductive support, a reinforcing structure, or any other appropriate description. The solder support may comprise a conductive material, a non-conductive material, or any combination of the two. The solder support 130 may have any appropriate shape, including a rectangular or other polygonal shape having a hollow center to allow for a conductive material. Likewise, the solder portion 141 may be alternatively described as a conductive portion, conductive material, or any similar description conveying the conductive nature of the solder portion 141.

Although a few embodiments of the present general inventive concept have been shown and described, it would be appreciated by those skilled in the art that changes may be made in these embodiments without departing from the principles and spirit of the general inventive concept, the scope of which is defined in the claims and their equivalents.

What is claimed is:

1. A method of forming a connection terminal, the method comprising:
preparing a substrate;
forming a first conductor of a tube shape having an opened upper portion on the substrate;
forming a second conductor on the first conductor; and
annealing the second conductor so that a portion of the second conductor extends in an internal space of the first conductor through the opened upper portion of the first conductor.

2. The method of claim 1, wherein forming the first conductor comprises:
forming a photoresist layer on the substrate;
forming a depression in the photoresist layer, the depression having a tube shape to expose the substrate; and
forming metal material on the substrate in the depression.

3. The method of claim 2, wherein preparing the substrate comprises forming a metal layer electrically connected to an electric device on the substrate, and
wherein forming the depression portion comprises exposing an edge region of the metal layer.

4. The method of claim 1, wherein the second conductor has a volume greater than a volume of the internal space of the first conductor.

5. The method of claim 1, wherein annealing the second conductor comprises reflowing the second conductor in a vacuum atmosphere.

6. The method of claim 1, wherein forming the first conductor comprises forming metal material having a higher melting point than the second conductor.

7. The method of claim 1, wherein forming the first conductor comprises forming metal material having a higher strength than the second conductor.

8. A method of forming a connection terminal, comprising:
forming a support structure on a substrate; and
forming a conductive material in a center portion of the support structure and extending out of an upper portion of the support structure,
wherein the conductive material is located above and electrically connected to a conductive contact of the substrate.

9. The method of claim 8, wherein the support structure is tube-shaped.

10. The method of claim 8, wherein forming the support structure comprises mounting a tube-shaped structure to the substrate.

11. The method of claim 8, wherein forming the support structure comprises:
forming a photoresist layer on the substrate;
forming a tube-shaped cavity in the photoresist layer to expose a portion of the substrate; and
filling the tube-shaped cavity with support material.

12. The method of claim 11, wherein the exposed portion of the substrate includes a portion of the conductive contact of the substrate; and
the support material is a conductive material.

13. The method according to claim 12, wherein the conductive contact has a substantially circular shape, and
the exposed portion of the conductive contact corresponds to an outer edge of the circular shape.

14. The method according to claim 11, wherein forming the conductive material includes:
after forming the tube-shaped cavity in the photoresist layer, filling a lower portion of the tube-shaped cavity with the support material;
filling an upper portion of the tube-shaped cavity with the conductive material;
removing the photoresist layer; and
causing the conductive material corresponding to the upper portion of the tube-shaped cavity to fill the center portion of the support structure and to extend out from an upper end of the support structure.

15. The method according to claim 8, wherein the conductive material extending out of an upper end of the support structure has a substantially spherical shape.

16. The method according to claim 8, wherein the support structure is of such a height that the conductive material extending out of the upper portion of the support structure is separated from a surface of the substrate.

17. The method according to claim 8, wherein the support structure is composed of a material having a structural strength greater than that of the conductive material.

18. The method according to claim 8, wherein the support structure is located outside an outer edge of the conductive contact.

19. A method of forming a connection terminal, the method comprising:
forming an external connector to be electrically connected to a metal connection pad of a substrate; and
forming a support structure between the metal connection pad of the substrate and the external connector so that the external connector is located a predetermined distance from the substrate.

20. The method according to claim 19, wherein the support structure includes a hollow center, the method including:
forming a conductive material in the hollow center of the support structure to electrically connect the metal connection pad to the external connector.
